(19) United States
(12) Patent Application Publication
(10) Pub. No.: US 2021/0133139 A1
(43) Pub. Date: May 6, 2021

(54) HOT-SWAPPABLE SOLID-STATE DRIVE EXPANSION CARDS

(71) Applicant: UNICOM Engineering, Inc. c/o UNICOM Systems, Inc., Mission Hills, CA (US)

(72) Inventors: Austin Keith Hipes, Plano, TX (US); Scott Brown, Burlington, MA (US); Jegatheeswaran Easwaramuthali, Framingham, MA (US); Jerry Lee Jarvis, S. Weymouth, MA (US)

(21) Appl. No.: 16/672,448

(22) Filed: Nov. 2, 2019

(51) Int. Cl. G06F 13/40; G06F 3/06

(52) U.S. Cl. CPC G06F 13/4081; G11C 5/04; G06F 3/0626

(57) ABSTRACT

An information storage module comprises a solid-state disk (SSD) drive enclosed in a housing that has one or more airflow inlets at a proximal end and one or more airflow outlets at a distal end. A connector disposed external to the housing at the distal end thereof supports electrical and mechanical coupling via a protocol that is hot-plug compatible. A connector disposed internal to the housing supports electrical and mechanical coupling in accord with an M.2 industry standard. The SSD drive comprises a circuit board having disposed thereon information-storage circuit elements and having a form factor per the M.2 standard, including, at a distal end of the board, an M.2-compatible edge connector that is slidably disposed in the internal connector of the housing. One or more plenums supporting airflow from the inlets to the outlets are disposed with the housing in a vicinity of the memory-storage circuit elements.

### BACKGROUND OF THE INVENTION

The invention pertains to digital data storage. It has application, by way of non-limiting example, to facilitating the addition and removal of storage devices to/from hosts, e.g., servers, client devices and other digital data apparatus.

Information storage technologies evolve. The post-industrial era has seen a dizzying succession of electromechanical, electromagnetic, magnetic, optical and a host of other storage technologies, each overtaking its predecessor in capacity, speed, and cost. The past decade alone has seen optical and electromagnetic technologies leap-frog one another in repeated succession.

Same as it ever was, an even newer storage technology is vying for mind- and market-share. Solid-state drives (SSDs) are a magnetic media that is rising in popularity in the computer storage marketplace, just as CD's and DVD's, the once-popular optical drives, are stumbling. Initially packaged to replace 2.5″ inertial disk drives, SSDs are now becoming available in the M.2 (a/k/a the NGFF) form factor, e.g., for use as expansion cards in notebook and tablet computers.

To the layperson, the M.2 form factor looks like a typical populated printed circuit board, albeit a small one. As those skilled in the art will appreciate, and as defined in “PCI Express M.2 Specification Revision 1.1,” (also known as the “PCI-SIG M.2 Specification”) and related publications, published by PCI-SIG, the teachings of which are incorporated herein by reference, this industry-standard form factor (hereinafter, the “M.2 standard”) calls for rectangular cards of between 12 mm and 30 mm and lengths of up to 110 mm. An edge connector on one of the narrow edges provides for electrical signal connectivity via PCI Express 3.0, Serial ATA (SATA) 3.0 and USB 3.0/2.0, while a semicircular hole at the center of the opposite edge provides for mechanical connectivity. M.2 cards (or modules) are usually installed by pushing the edge connector into a socket on a host circuit board and securing the other end to the same board via a screw.

While M.2 SSD drives are a potential boon to digital equipment users, both at the enterprise and consumer levels, the rise of that storage medium and the corresponding fall of optical drives presents both an opportunity and a challenge to manufacturers, integrators, and others in the digital equipment ecosystem.

An object of the invention is to provide improved systems, apparatus and methods for digital data storage.

A related object of the invention is to provide such systems, apparatus and methods as facilitate the addition and removal of storage to/from servers, client devices and other digital data apparatus.

A further object of the invention is to provide such systems, apparatus and methods as capitalize on the rise of the M.2 form factor SSDs and the corresponding fall of optical drives in the marketplace.

Still yet a further object of the invention is to provide such systems, apparatus and methods as support hot-plugging (a/k/a “hot swapping”), i.e., the addition and removal of a storage device while a host device is running and with automatic recognition of the change by the host device's operating system.

### SUMMARY OF THE INVENTION

The foregoing are among the objects attained by the invention, which provides in some aspects an information storage module with a solid-state disk (SSD) drive in the form factor of the M.2 industry standard. A housing that encloses the SSD drive has airflow inlets and airflow outlets. A connector disposed internal to the housing supports electrical and mechanical coupling of the SSD drive in accord with the M.2 standard. A connector disposed external to the housing is coupled to the internally disposed connector and supports electrical and mechanical coupling of the module, e.g., to a host device, via a protocol that is hot-plug compatible. As a consequence, the module can be hot-plugged into a suitable host digital data device without interruption of its operations.

According to a related aspect of the invention, the SSD drive comprises a circuit board that includes, at a distal end, an M.2-compatible edge connector that is slidably disposed in the internal connector of the housing. One or more plenums supporting airflow from the inlets to the outlets are disposed within the housing in a vicinity of memory-storage circuit elements of the SSD drive.

The invention provides, in other aspects, an information storage module, e.g., as described above, in which one of the plenums is defined by rails disposed on an internal surface of the housing. Those rails can be arranged to funnel airflow received at the proximal end of the housing toward a medial portion of the SSD drive distal of the proximal end.

The invention provides, in related aspects, an information storage module, e.g., as described above, in which the circuit board includes a recess at a proximal end in accord with the M.2 standard, and in which the housing includes an internal mount disposed on an internal surface thereof for affixing the circuit board via that recess. A space defined between that internal surface and an opposing surface of the SSD drive defines at least one of the aforesaid plenums.

Further aspects of the invention provide an information storage module, e.g., as described above, in which the connector disposed external to the housing at the distal end supports electrical and mechanical coupling via a socket connector compatible with industry-standard protocols such as PCI Express 3.0, Serial ATA (SATA) 3.0 and USB 3.0/2.0, all by way of non-limiting example.

Further aspects of the invention provide a storage module, e.g., as described above, that includes a status indicator, such as an LED or other electroluminescent device that is disposed on the proximal end of the module (e.g., for ready viewing by an operator of a host digital data device in which the module is mounted) and that indicates when the storage module is active or otherwise.

In other aspects, the invention provides an information storage unit comprising a tray that is adapted to receive and to electro-mechanically couple two or more information storage modules, e.g., of the type described above. The tray includes multiple internal electro-mechanical connectors, each adapted to receive a respective one of the modules and to establish hot-plug communications coupling therewith. Each of those internal connectors can be disposed at a distal end of a respective bay of the tray adapted to receive the respective module. A faceplate or other covering structure at a proximal end of the tray can include multiple apertures, each adapted to facilitate slidably receiving a module into a respective one of the bays.

The information storage unit, tray, internal connectors, faceplate (or other covering) and apertures are adapted to permit airflow (e.g., from the ambient environment external to a host digital data device in which the storage unit is mounted) to reach airflow inlets and exit airflow outlets of modules disposed in the information storage unit substantially unobstructed. As used herein, “substantially unobstructed” means absent obstruction that would prevent that airflow from cooling to expected operating temperatures the SSDs disposed within the modules under expected operating conditions.

A related aspect of the invention provides an information storage unit, e.g., as described above, having one or more of the above-described modules disposed therein.

The information storage unit further includes one or more external connectors that are coupled to the internal electro-mechanical connectors to support hot-plug communications—and, therefore, hot-plug mounting—between module(s) contained in the tray and a host digital data device to which the information storage unit is coupled. The external connector(s) can be disposed at a distal end of the information storage unit for electrical coupling with the host digital data apparatus, e.g., via a corresponding electro-mechanical socket disposed therein or thereon.

In other aspects, the invention provides an information storage unit, e.g., as described above, in which the modules store information in accord with a RAID (redundant array of independent disks) protocol. Such storage can be under control of logic provided within the information storage unit, a host digital data device or otherwise.

In still other aspects, the invention provides an information storage unit, e.g., as described above, sized to be received slidably or otherwise in a slim disk drive bay of a host digital data device. This can be, for example, a bay of approximately 9.5 mm (or otherwise) in height of the type commonly used to receive a slim optical disk drive or a slim floppy disk drive. According to related aspects of the invention the external connectors of the information storage module and/or information storage unit are electrically and mechanically compatible with an industry-standard Slimline SATA specification.

Other aspects of the invention provide a housing of the type described above that is configured to receive a solid-state disk (SSD) drive and that has one or more airflow inlets at proximal end and one or more airflow outlets at a distal end. A connector disposed external to the housing at the distal end thereof supports electrical and mechanical coupling via a protocol that is hot-plug compatible. A connector disposed internal to the housing supports electrical and mechanical coupling in accord with an M.2 industry standard. One or more plenums supporting airflow from the inlets to the outlets are disposed within the housing and are adapted to cool memory-storage circuit elements of an SSD drive in a vicinity thereof.

The foregoing and other objects of the invention are evident in the drawings and in the discussion that follows.

### BRIEF DESCRIPTION OF THE DRAWINGS

A more complete understanding of the invention may be attained by reference to the drawings, in which:

FIG. 1 depicts an information storage module according to one practice of the invention;

FIG. 2 is an exploded view of the information storage module of FIG. 1;

FIG. 3 is an exploded view of a information storage unit according to one practice of the invention;

FIG. 4 is a perspective view of the information storage of FIG. 4;

FIG. 5 depicts airflow through the information storage unit of FIGS. 3-4; and

FIG. 6 depicts a digital data apparatus in which information storage units according to FIGS. 3-4 are mounted.

### DETAILED DESCRIPTION OF THE ILLUSTRATED EMBODIMENT

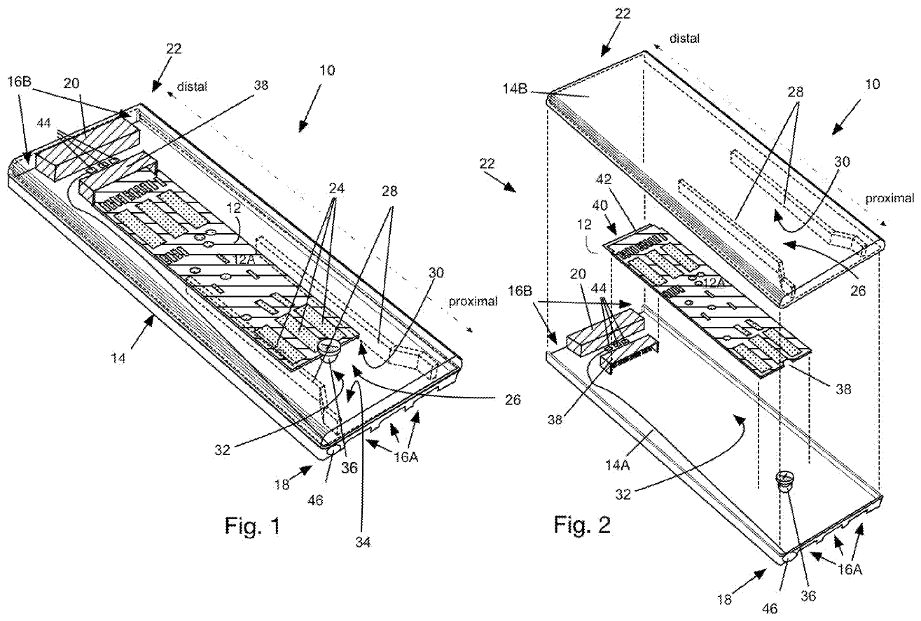

FIGS. 1-2 are perspective and exploded views, respectively, of an information storage module 10 according to one practice of the invention comprising a solid-state disk (SSD) drive 12 enclosed in a housing 14, as illustrated and described below. The SSD drive 12 is a conventional storage device of the type known in the art having a form factor per the M.2 standard, e.g., as set forth in incorporated by reference “PCI Express M.2 Specification Revision 1.1” (also known as the “PCI-SIG M.2 Specification”) and related publications published by PCI-SIG. Illustrated housing 14 contains, protects and provides operational air-cooling for the drive 12, as well as making it hot-pluggable in a host digital data device of the type shown as element 58 in FIG. 6 or otherwise. As noted above, a hot-pluggable device is one that can be added to or removed from such a host device 58 while it is running and with automatic recognition of such addition or removal by the host's operating system.

Housing 14

Illustrated housing 14 comprises two portions: an upper portion 14A and a lower portion 14B, though other embodiments may comprise a fewer or greater number thereof. These are fabricated of metal, e.g., aluminum, in the illustrated embodiment; although the use of plastics, ceramics or other materials, or a combination of the foregoing, is within the ken of those skilled in the art in view of the teachings hereof. The portions 14A, 14B may be secured together by screws, pins, clips or other fasteners, removable or otherwise, or they may be glued, welded or otherwise bonded, all per convention in the art as adapted in accord with the teachings hereof.

The housing 14 includes airflow inlets 16A on a proximal end and airflow outlets on a distal end 22. Three airflow inlets 16A and two airflow outlets 16B are shown in the drawing, though a lesser or greater number may be employed. The inlets and outlets can be special-purpose apertures, e.g., as in the case of inlets formed from apertures 16A in lower portion 14A, or they may result de facto from the positions of other components, e.g., as in the case of outlets formed from gaps 16B between the lateral ends of the connector 20 (discussed below) and the inside walls of the upper portion 14B at the distal end 22 of the housing 14. The inlets and outlets 14A, 14B are sized, numbered and arranged to permit sufficient ambient air (e.g., air in an environment external to host device 58) to be drawn through the housing 14 by a fan 60 disposed within a host digital data device 58 (FIG. 6) to cool the SSD drive 12 to expected operating temperatures when the module 10 is operating under expected operating conditions.

In this regard, the housing 14 defines one or more plenums through which that air can flow in order to cool components of the SSD drive 12 expected to run the hottest under those operating conditions. This includes the memory-storage circuit elements 24 of the drive 12—that is, the semiconductor chips in which information is principally stored on the drive 12. This can also include processing and control circuit elements, resistors and other circuit elements that tend to “run hot” during operation of the module 10.

By way of example, the module 10 of the illustrated embodiment includes one such plenum 26 “above” (relatively speaking) the SSD drive 12 in the vicinity of elements 24 on the “upper side” (again, relatively speaking) of that drive. That plenum 26 is defined by rails 28 disposed on an internal surface 30 of upper portion 14B of the housing 14, as well as by that surface and an opposing surface of the SSD drive 12. Although rails 28 configured as shown in the drawing are used to funnel airflow received via inlets 16A at the proximal end of the housing 14 over the elements 24 and toward a distal end of the housing, as shown in FIG. 5 with respect to two modules 10 disposed in the information storage unit 48 depicted there, it will be appreciated that other structures—in addition to or instead of those rails—may be employed to facilitate cooling those elements 24, as is within the ken of those skilled in the art in view of the teachings hereof.

By way of further example, the illustrated embodiment includes another such plenum 32 “below” the SSD drive 12. This can be in the vicinity of additional memory-storage elements (not shown) on the “underside” of the SSD drive 12 or other elements that tend to run hot there. That plenum 32 can be defined by the space between the internal surface 34 of the lower portion 14A of the housing 14 and an opposing surface of the SSD drive 12—particularly, in the gap formed between those surfaces when the drive 12 is secured by the internal mount 36 that is disposed in the lower portion 14A of the housing 14 and that secures the SSD drive 12 thereto via the mechanical mounting recess 38 provided at the proximal end of the SSD drive 12 in accord with the M.2 standard.

Although two airflow plenums 26 and 32 are discussed above and highlighted in the drawings, it will be appreciated that additional such plenums may be provided in the illustrated and other embodiments and, conversely, that some embodiments may forego many or all of those plenums, depending on the cooling requirements of the SSD drive 12 and other constituent components of the module 10.

Housing 14 includes an internally disposed socket connector 38 shown, here, mounted on surface 34 of the lower portion 14A of the housing but, potentially, disposed elsewhere therein. That socket 38, which receives the edge connector of the drive 12, supports electrical and mechanical coupling in accord with the M.2 standard.

The housing 14 additionally includes a connector 20 disposed at least partially external to the housing at the distal end 22 supports electrical and mechanical coupling via a socket connector compatible with industry-standard protocols such as PCI Express 3.0, Serial ATA (SATA) 3.0 and USB 3.0/2.0, all by way of example. In the illustrated embodiment, the socket 20 is in the Slimline SATA form factor, again, by way of example.

Illustrated circuitry 44 provides electrical signal coupling between connector 20 and connector 38 and, when the SSD drive 12 is mounted in connector 38, between that drive and a host digital data processor or other device to which connector 20 is, in turn, coupled. The circuitry 44 is adapted to provide a suitable interface between the respective connectors and the devices to which they are coupled, including, for example, providing signal conditioning, interfacing, buffering, and so forth, so as to permit reliable communications between the connectors and respective devices. This includes interfacing between the respective device protocols in such a manner, for example, as to permit the SSD drive 12 and, more generally, module 10, to be hot-plugged into (and remove from) such a host digital data device. The design and operation of circuitry 44 for such a role is within the ken of those skilled in the art in view of the teachings hereof.

Circuitry 44 can also be adapted to drive a status indicator 46 disposed on a proximal end 18 of the module 10 to indicate when the module and, particularly, for example, the SSD drive 12, is active (e.g., reading/writing data or otherwise). The indicator 46 can be an LED or other electroluminescent device of the type known in the art for such purpose.

SSD Drive 12

The SSD drive 12 is a conventional storage device of the type known in the art having a form factor per the M.2 standard, e.g., as set forth in incorporated by reference “PCI Express M.2 Specification Revision 1.1,” (also known as the “PCI-SIG M.2 Specification”) and related publications published by PCI-SIG. As such, the drive 12 comprises a printed circuit board (PCB) 12A having circuit elements—including for example, the aforementioned memory-storage circuit elements 24, processing and control circuit elements, and so forth—providing for storage of 256 MBytes-2 TBytes or other capacities, all as per convention in the art. Also per convention, SSD drive 12 comprises at its distal end 40 an M.2-compatible edge connector adapted to be slidably disposed in the internal connector 38 per convention in the art.

Information Storage Unit 46

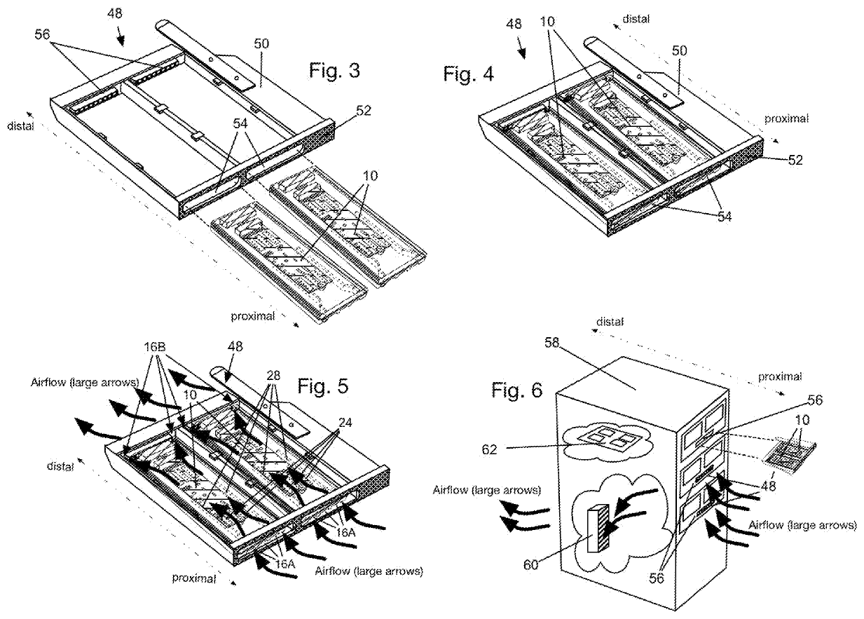

FIGS. 3-4 are exploded and perspective views, respectively, of an information storage unit 48 according to one practice of the invention having a tray 50 adapted to receive and to electro-mechanically couple one or more information storage modules 10 of the type described above. Illustrated unit 48 is adapted to receive two such modules, though, other embodiments may vary in this regard. The unit 48 of the illustrated embodiment is shaped and sized to be affixed and/or received slidably or otherwise in a slim disk drive bay 56 of a host digital data device 58, though other embodiments may utilize units 48 of differing shapes, sizes or other configurations.

Illustrated storage unit 48 and tray 50 are fabricated of metal, e.g., aluminum, in the illustrated embodiment, although the use of plastics, ceramics or other materials, or a combination of the foregoing, is within the ken of those skilled in the art. Securement may be via screws, pins, clips or other fasteners, removable or otherwise, or via glue, welds or other bonding, all per convention in the art as adapted in accord with the teachings hereof.

In the illustrated embodiment, the two information storage modules 10 of information storage unit 48 are slidably received in respective bays 50A and 50B of tray 50 through faceplate 52 or other covering structure at a proximal end of the tray 50 (and, specifically, at the proximal ends of the respective bays 50A, 50B)—and, more particularly, through respective apertures 54 of those faceplates—as illustrated in the drawings. In embodiments such as that illustrated here, the faceplate (or other covering) 52, apertures 54, tray 50 and other components of the unit 48 are sized and arranged to permit airflow from the external environment or otherwise reach airflow inlets 16A and exit airflow outlets 16B of modules 10 disposed in the information storage unit 48 substantially unobstructed. See FIG. 5, discussed above. As used herein, “substantially unobstructed” means absent obstruction that would prevent that airflow from cooling to expected operating temperatures the SSDs 12 and other components disposed within the modules 10 under expected operating conditions.

Although those bays 50A, 50B are disposed laterally adjacent and parallel to one another in the illustrated embodiment, other embodiments may vary in this regard. Thus, for example, the module-retaining bays may be in-line, stacked or arranged in some other configuration suited for the use-case at hand, all as is within the ken of those skilled in the art in view of the teachings hereof.

Tray 50 includes internal electro-mechanical connectors 56, each disposed at a distal end of the respective bay 50A, 50B, as illustrated, and adapted to receive the corresponding external connector 20 of the respective module 10. The connectors 56 are selected in accord with the type and gender of the corresponding external connectors 20 and are provided with such logic (not shown) as is necessary for providing signal conditioning, interfacing, buffering, and so forth, so as to permit reliable communications between the respective connectors and respective upstream and downstream devices (e.g., SSDs 12 and host digital data device 58 of FIG. 6) to which they are coupled —all as is within the ken of those skilled in the art in view of the teachings hereof.

The information storage unit 48 can include one or more external connectors (not shown) that are coupled to the internal electro-mechanical connectors 56 to support hot-plug communications between modules 10 contained in the tray 50 and a host digital data device 58 in which the information storage unit 48 is inserted or otherwise coupled. The external connector(s) can be disposed at a distal end the information storage unit 48 for electrical coupling with the host digital data apparatus, e.g., via electro-mechanical socket disposed therein or thereon—all as per convention in the art as adapted in accord with the teachings hereof.

Digital Data Device 58

FIG. 6 depicts a digital data apparatus 58 with one or more information storage units 48 according to the invention. Illustrated apparatus 58 is a server-class digital data processor, although it may comprise a computer or digital data processor of another type or, alternatively, may be a digital data device of another type altogether. This includes, by way of example, a medical device, laboratory equipment or other apparatus that utilizes digital data and that is capable of interfacing with one or more storage units 48 via their external connectors or otherwise. In the illustrated embodiment, one such unit 48 is being readied for insertion in an upper drive bay 56 of the apparatus 58, and two such units 48 are shown already inserted in two other respective bays 56.

Logic 62 native to the apparatus 58 can drive the modules 10 to store information in accord with an industry-standard RAID (redundant array of independent disks) protocol. That logic can be dedicated RAID controller logic of the type commercially available in the marketplace or, alternatively, can be software RAID logic executed, for example, by a CPU of the apparatus 58.

In the illustrated embodiment, the RAID logic (whether dedicated or CPU-executed) stores and retrieves data from the paired modules 10 of each unit 48 in accord with the so-called RAID 0 protocol. In embodiments in which the units 48 include additional modules 10, other RAID protocols can be used. Of course, some embodiments do not use RAID protocols at all and, rather, merely store data independently within each module 10 of the units 48. Although RAID control is provided by logic 62 of the host digital data device 58 of the illustrated embodiment, in other embodiments logic onboard the individual storage units 48 and/or modules 10 may provide such control instead or in addition. The utilization of logic 62 (or corresponding logic on-board the units 48 or modules 10) for RAID control of information storage in modules 10 is within the ken of those skilled in the art in view of the teachings hereof.

Operation

In operation, one or more information storage units 48 are inserted or otherwise mounted in a server 58 or other digital data apparatus. One or more information storage modules 10 can be inserted into each such unit 48, before or after the apparatus is operational. Because the modules 10 are hot-swappable, they are recognized by the operating system of apparatus 58 automatically—e.g., without the need for a reboot—and ready for use in information storage or retrieval by that apparatus 58. In embodiments, in which the storage units 48 include two or more modules 10 (e.g., as is the case here) and in which logic 62 (or logic onboard the units 48 or modules 10) is used for RAID control, one of the modules 10 can be removed at a time, e.g., for replacement or otherwise, without disruption of operation of the host device 58 (although access speeds to information on the remaining module may be slowed).

To prevent overheating of the modules 10, e.g., during information storage or retrieval thereto/therefrom, fan 60 of the host digital data device 58 can be operated to pull air from the environment external to the apparatus 58 through the modules by way of their respective airflow inlets and outlets 16A, 16B, thereby, cooling the storage circuit elements 24 on those modules, as discussed above. This is represented by the large airflow-representative arrows in FIG. 6

Described herein and shown in the drawings are embodiments meeting the objects of the invention, among others. It will be appreciated that the illustrated embodiment is merely an example of the invention and that other embodiments deviating from those shown and described here fall within the scope of the invention, of which we claim:

1. An information storage module, comprising
A. a solid-state disk (SSD) drive including a circuit board having disposed thereon information-storage circuit elements and having a form factor per an M.2 industry standard,
B. a housing that encloses the SSD drive and that has one or more airflow inlets at a proximal end of the housing and one or more airflow outlets at a distal end of the housing, the housing being adapted to be slidably received into and operationally disposed in an information storage unit that, in turn, is adapted to be slidably received into and operationally disposed in a disk drive bay of substantially 9.5 mm in height of a digital data device,
C. a connector disposed internal to the housing that supports electrical and mechanical coupling of the SSD drive in accord with the M.2 industry standard,
D. the housing having an externally-exposed connector disposed thereon that is coupled to the internally disposed connector and that supports electrical and mechanical coupling of the module via a protocol that is hot-plug compatible,
E. a plurality of airflow plenums internal to the module, each plenum supporting airflow from the airflow inlets to the airflow outlets to cool elements disposed on the circuit board, the plurality of airflow plenums including
(i) a first plenum supporting airflow within the housing flowing over information-storage circuit elements on an upper side of the circuit board, the first plenum being defined by one or more rails disposed on an internal surface of an upper side of the housing and by the upper side of the circuit board opposing that upper side of the housing, the one or more rails funneling airflow received at a said airflow inlet toward a medial portion of the SSD drive distal of the proximal end of the housing,
(ii) a second plenum supporting airflow within the housing flowing over the information-storage circuit elements on an underside of the circuit board, the second plenum being defined within the housing between an internal mounting surface of a lower side of the housing and an opposing surface of the circuit board.

2-3. (canceled)

4. The information storage module of claim 1, wherein the airflow inlets and outlets are configured to permit sufficient air to be drawn through the housing by a fan disposed within a host digital data device to cool the SSD drive to expected operating temperatures when the module is operating when under expected operating conditions.

5-6. (canceled)

7. The information storage module of claim 1, wherein the externally-exposed connector of the module is a SATA slimline connector.

8. The information storage module of claim 1, wherein the externally-exposed connector of the module supports electrical and mechanical coupling via a connector compatible with any of industry-standard protocols PCI Express 3.0, Serial ATA (SATA) 3.0 and USB 3.0/2.0.

9. The information storage module of claim 1, comprising a light-emitting diode or other electroluminescent status indicator disposed on the proximal end of the module.

10. An information storage unit, comprising
A. a tray that is adapted to receive and to electro-mechanically couple one or more information storage modules, the tray being shaped and sized to be slidably received into and operationally disposed in a slim disk drive bay of a host digital data device,
B. each information storage module comprising
i. a solid-state disk (SSD) drive comprising a circuit board having disposed thereon information-storage circuit elements and having a form factor per an M.2 industry standard,
ii. a housing that encloses the SSD drive and that has one or more airflow inlets and one or more airflow outlets,
iii. a connector disposed internal to the housing that supports electrical and mechanical coupling of the SSD drive in accord with the M.2 industry standard,
iv. a connector disposed external to the housing that is coupled to the internally disposed connector and that supports electrical and mechanical coupling of the module via a protocol that is hot-plug compatible,
v. one or more plurality of airflow plenums internal to the module, each plenum supporting airflow from the airflow inlets to the airflow outlets to cool the elements disposed on the circuit board, the one or more airflow plenums including at least one of
(i) a first plenum supporting airflow within the housing flowing over said information-storage circuit elements on an upper side of the circuit board, the first plenum being defined by one or more rails disposed on an internal surface of an upper side of the housing and by a side of the circuit board opposing that upper side of the housing, the one or more rails funneling airflow received at a said airflow inlet toward a medial portion of the SSD drive distal of the proximal end of the housing,
(ii) a second plenum supporting airflow within the housing flowing over the information-storage circuit elements on an underside of the circuit board, the second plenum being defined within the housing between an internal mounting surface of a lower side of the housing and an opposing surface of the circuit board,
C. the tray including multiple internal electro-mechanical connectors, each adapted to receive a respective one of the modules and to establish hot-plug communications coupling therewith.

11. The information storage unit of claim 10 having one or more external connectors that are coupled to the internal electro-mechanical connectors to support hot-plug communications between module(s) contained in the tray and a host digital data device to which the information storage unit is coupled.

12. The information storage unit of claim 10 having a faceplate or other covering structure disposed at a proximal end of the tray to slidably receive a module for insertion into a respective one of the bays.

13. The information storage unit of claim 12, wherein the modules store information in accord with a RAID (redundant array of independent disks) protocol.

14. The information storage unit of claim 12, wherein the storage unit is sized to be slidably received into and operationally disposed in a slim disk drive bay of a host digital data device.

15. The information storage unit of claim 10, wherein at least one module comprises one or more plenums supporting airflow from the airflow inlets to the airflow outlets, where the one or more plenums are disposed within the housing in a vicinity of information-storage circuit elements.

16. The information storage unit of claim 10, wherein the airflow inlets of at least one module are disposed at a proximal end of the module and the airflow outlets are disposed at a distal end of the module.

17. The information storage unit of claim 10, wherein the airflow inlets and outlets of at least one module are configured to permit sufficient air to be drawn through the housing by a fan disposed within a host digital data device to cool the SSD drive to expected operating temperatures when the module is operating under expected operating conditions.

18. The information storage unit of claim 10, wherein the housing of at least one module includes one or more rails disposed on an internal surface thereof defining a said plenum.

19. The information storage unit of claim 18 in which the one or more rails are arranged to funnel airflow received at the proximal end of the housing of the respective module toward a medial portion of the SSD drive distal of the proximal end.

20. The information storage unit of claim 10, wherein at least one modules a light-emitting diode or other electroluminescent status indicator disposed on the proximal end of the module.

21. An information storage unit, comprising
A. one or more information storage modules, each including
i. a housing that is adapted to enclose a circuit board having disposed thereon one or more information-storage circuit elements,
ii. one or more airflow inlets at a proximal end of the housing and one or more airflow outlets at a distal end of the housing,
iii. one or more airflow plenums internal to the module, each supporting airflow from the airflow inlets to the airflow outlets to cool the one or more information-storage circuit elements disposed on the circuit board, the airflow plenums including a first plenum supporting airflow within the housing flowing over information-storage circuit elements on a first side of the circuit board, the first plenum being defined by one or more rails disposed on an internal surface of the housing opposing the first side of the circuit board and being further defined by that internal surface of the housing and that first side of the circuit board, the one or more rails funneling airflow received at a said airflow inlet toward a portion of the circuit board where the information-storage elements are disposed
B. a tray that is adapted to receive and to electro-mechanically couple the one or more information storage modules, the tray being shaped and sized to be slidably received into and operationally disposed in an externally exposed bay of a host digital data device,
C. wherein the tray permits airflow from an external environment to reach the airflow inlets and to exit the airflow outlets of the one or more modules substantially unobstructed.

22. The information storage unit of claim 21, wherein the airflow plenums internal to the module include a second plenum supporting airflow within the housing flowing over the information-storage circuit elements on a second side of the circuit board, the second plenum being defined within the housing between that second side of the circuit board and an internal surface of the housing opposing the second side of the circuit board.

23. The information storage unit of claim 21, the housing having a connector disposed thereon that is coupled to the internally disposed connector and that supports electrical and mechanical coupling of the module via a protocol that is hot-plug compatible.

24. The information storage unit of claim 21, wherein the housing is adapted to be slidably received into and operationally disposed in said externally disposed bay that is substantially 9.5 mm in height.

25. The information storage unit of claim 21, wherein the housing includes an internal connector that slidably receives the circuit board.

26. (canceled)

27. The information storage unit of claim 21, including one or more internal electro-mechanical connectors, each adapted to receive a respective one of the modules and to establish hot-plug communications coupling therewith.

28. The information storage unit of claim 27 having one or more external connectors that are coupled to the internal electro-mechanical connectors to support hot-plug communications between module(s) contained in the tray and a host digital data device to which the information storage unit is coupled.

29. The information storage unit of claim 21, having a faceplate or other covering structure disposed at a proximal end of the tray to slidably receive a module for insertion into a respective one of the bays.

30. (canceled)
